(19) United States
(12) Patent Application Publication
(10) Pub. No.: US 2026/0107745 A1
(43) Pub. Date: Apr. 16, 2026

(54) METHOD OF FORMING A THIN FILM USING HYDROGEN TREATMENT

(71) Applicant: ASM IP Holding B.V., Almere (NL)

(72) Inventors: Estiaque Haidar Shourov, Mesa, AZ (US); Balaji Kannan, Phoenix, AZ (US); Jian-Wei Liang, Scottsdale, AZ (US); Mojtaba Samiee, Tempe, AZ (US); Madhan Kumar Arulanandam, Tempe, AZ (US); Ali Al janabi, Scottsdale, AZ (US); Wei Li, Chandler, AZ (US)

(21) Appl. No.: 19/351,418

(22) Filed: Oct. 7, 2025

Related U.S. Application Data
(60) Provisional application No. 63/705,575, filed on Oct. 10, 2024.

(51) Int. Cl. H01L 21/321; C23C 16/34; C23C 16/455; C23C 16/56; H01L 21/3205

(52) U.S. Cl. CPC H10P 95/00; C23C 16/34; C23C 16/45525; C23C 16/56; H10P 14/412

(57) ABSTRACT

A substrate processing method for forming a thin film includes providing or forming a transition metal nitride film on a substrate in a reaction chamber and exposing the transition metal nitride film to a hydrogen treatment to form a treated transition metal compound film. The hydrogen treatment may lower the resistivity of the transition metal nitride film and/or be used to desirably tune other properties and/or composition of the transition metal nitride film.

### CROSS-REFERENCE TO RELATED APPLICATIONS

This application is a nonprovisional of, and claims priority to and the benefit of, U.S. Provisional Patent Application No. 63/705,575 , filed Oct. 10, 2024 and entitled “METHOD OF FORMING A THIN FILM USING HYDROGEN TREATMENT,” which is hereby incorporated by reference herein.

### FIELD

Examples are described that relate to a method for forming a thin film, as well as a structure comprising the thin film and a substrate processing apparatus for forming the thin film. More particularly, examples of the disclosure relate to a method of forming a thin film using a hydrogen treatment step and to an apparatus for forming the thin film.

### BACKGROUND

The scaling of semiconductor devices has led to significant improvements in speed and density of integrated circuits. However, conventional device scaling techniques face significant challenges for future technology nodes.

For example, one challenge has been finding suitable methods for forming conductive thin films with desirable properties, such as thickness and resistivity, that also are efficient and repeatable. Cyclical deposition processes may be used to efficiently and repeatably deposit a thin film, but such processes may produce a film with undesirable properties, such as relatively high resistivity. To produce a thin film with more desirable properties, there exists a desire for methods to tune properties of thin films to produce treated thin films, such as treated transition metal nitrides or carbides, with desirable properties. Additionally, there exists a desire for treatments that modify the properties of a deposited thin film at relatively low temperatures and pressures to minimize potential damage to other layers or features within structures.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY

This summary is provided to introduce a selection of concepts in a simplified form. These concepts are described in further detail in the detailed description of example embodiments of the disclosure below. This summary is not intended to necessarily identify key features or essential features of the claimed subject matter, nor is it intended to be used to limit the scope of the claimed subject matter.

Examples described herein provide a substrate processing method, substrate processing apparatus, and a structure on a substrate. Various examples of the substrate processing method provide for the deposition and treatment of a thin film to form a treated thin film. The methods disclosed herein provide thin films (e.g., treated transition metal compound films, treated transition metal nitride films or treated metal transition carbide films) with desired properties, such as relatively low resistivity 400 μΩ cm.

According to one or more embodiments, a method for the forming of a thin film is provided. An exemplary method includes providing a substrate in a reaction chamber. In some embodiments, the substrate comprises a transition metal nitride film on the surface of the substrate. In other embodiments, the method includes depositing a transition metal nitride film on the substrate. An exemplary method can further include exposing the transition metal nitride film to a hydrogen treatment to form a treated transition metal compound film. In some embodiments, the treated transition metal compound film may be a treated transition metal nitride film. In some embodiments, the treated transition metal compound film may be a treated transition metal carbide film. The treated transition metal compound film may have a resistivity lower than the transition metal nitride film.

In accordance with examples of one or more embodiments, the step of depositing a transition metal nitride comprises a cyclical deposition process, such as an atomic layer deposition (ALD) process. An exemplary cyclical deposition process includes pulsing a transition metal precursor to the reaction chamber and pulsing a nitrogen reactant to the reaction chamber. Exemplary transition metal precursor may comprise one or more metalorganic precursors. In some examples, the transition metal precursor comprises one or more of amido groups. In some examples, the transition metal precursor comprises one or more imido groups. In some examples, the transition metal precursor comprises at least one amido group and at least one imido group. In some examples, the transition metal precursor comprises a transition metal imido complex. In some examples, the transition metal precursor comprises bis(tert-butylimido) bis(dimethylamido) metal compound, such as bis(tert-butylimido) bis(dimethylamido)tungsten(vi), or bis(tert-butylimido) bis(dimethylamido)molybdenum. The nitrogen reactant may comprise a nitrogen-containing reactant, such as one or more of ammonia (NH₃), hydrazine (N₂H₄), nitrogen (N₂), a mixture of nitrogen (N₂) and hydrogen (H₂), or the like. In some embodiments, the cyclical deposition process is repeated a (e.g., predetermined) number of times until the transition metal nitride film reaches a predetermined or desired thickness. In some embodiments, the transition metal nitride film has a thickness less than about 150 Angstroms, less than about 100 Angstroms, less than about 50 Angstroms, or greater than about 8 Angstroms, or greater than about 20 Angstroms.

In some embodiments, the transition metal nitride film comprises a Group 6 metal. In various examples of these embodiments, the transition metal nitride film comprises one or more of tungsten or molybdenum.

In some embodiments, the transition metal nitride film comprises a transition metal and nitrogen. The transition metal nitride film may comprise an atomic percentage of transition metal between about 20 at % and about 75 at%, or about 25 at % to 70 at %, or about 30 at % to about 50 at %. The transition metal nitride film may comprise an atomic percentage of nitrogen between about 20 at % and about 45 at %, or about 25 at % to about 35 at %.

In some embodiments, the transition metal nitride film comprises a transition metal, carbon, and nitrogen. In some embodiments, the transition metal nitride film comprises an atomic percentage of carbon between about 15 at % and about 35 at %, or about 20 at % to about 25 at %. In some embodiments, the transition metal nitride film has a resistivity from about 2600 to about 4000 μΩ cm for thicknesses greater than about 20 Angstroms. In some embodiments, the transition metal nitride film has a resistivity from about 2600 to about 4000 μΩ cm for thicknesses greater than about 20 Angstroms. In some embodiments, the transition metal nitride film has a resistivity from about 26000 to about 40000 μΩ cm for thicknesses less than about 20 Angstroms.

In some embodiments, the transition metal nitride film comprises oxygen with an atomic percentage of oxygen between about 0 at % and about 30 at %, or about 10 at % and about 30 at %, or about 15 at % to about 25 at %.

In some embodiments, exposing the transition metal nitride film to the hydrogen treatment comprises exposing the transition metal nitride to H₂. The hydrogen treatment may be a thermal process. In some cases, the hydrogen treatment may not use a plasma. In some embodiments, exposing the transition metal nitride film to the hydrogen treatment comprises exposing the transition metal nitride film to hydrogen for about 0.1 minutes to about 40 minutes, or about 10 minutes to about 30 minutes, or about 1 minutes to about 20 minutes.

According to one or more examples, a pressure during the step of exposing the transition metal nitride film to the hydrogen treatment is less than about 300 Torr, or less than about 200 Torr, or between about 1 Torr and about 100 Torr.

According to one or more examples, a temperature during the step of exposing the transition metal nitride film to the hydrogen treatment is from about 300° C. to about 550° C., or between about 400° C. and about 525° C., or between about 475° C. and about 510° C.

In accordance with examples of the embodiments, the hydrogen treatment changes a composition and/or property of the transition metal nitride film. In some embodiments, the hydrogen treatment removes nitrogen from the transition metal nitride film. In some embodiments, the hydrogen treatment lowers a number of C═C bonds in the transition metal nitride film. In some embodiments, the hydrogen treatment lowers the amount of metal to nitrogen bonds and increases the amount of metal to carbon bonds.

In accordance with further examples, the hydrogen treatment is not a deposition process. The hydrogen treatment may not deposit an additional film on the transition metal nitride film.

In some embodiments, the step of exposing the transition metal nitride film to the hydrogen treatment forms a treated transition metal compound film. In some embodiments, the hydrogen treatment may form a treated transition metal nitride film by changing the composition and/or properties of the transition metal nitride film. In some embodiments, the hydrogen treatment may form a treated transition metal carbide film from the transition metal nitride film. In such embodiments, the hydrogen treatment may reduce the amount of metal to nitrogen bonds and increase the number of metal to carbon bonds. In some embodiments, the treated transition metal compound film comprises less nitrogen than the transition metal nitride film. In some embodiments, the treated transition metal compound film comprises an atomic percentage of nitrogen between about 5 at % and about 25 at %, or about 7 at % to about 15 at %. In some embodiments the treated transition metal compound film has a ratio of transition metal atoms to nitrogen atoms of about 2.5:1 to about 5:1, or about 3:1 to about 4:1. In some embodiments, the treated transition metal compound film comprises substantially the same amount of the transition metal, oxygen, and carbon as the transition metal nitride film. In some embodiments, a ratio between the transition metal and carbon in the transition metal nitride film is within about 10 % of a ratio between transition metal and carbon in the treated transition metal compound film. The treated transition metal compound film may have a resistivity less than 400 μΩ cm, or from about 300 μΩ cm to 600 μΩ cm, or about 350 μΩ cm to 500 μΩ cm, or about 375 μΩ cm to about 425 μΩ cm for thicknesses greater than about 20 Angstroms. The treated transition metal compound film may have a resistivity less than about 4000 μΩ cm, or less than about 3250 μΩ cm, or less than about 2600 μΩ cm for thicknesses less than about 20 Angstroms. In some embodiments, the treated transition metal compound film may have a resistivity between about 60% to 90% less, or between about 80 to 88% less than the resistivity of the transition metal nitride film.

In accordance with further examples of the disclosure, a device is formed using a method and/or include a structure as described herein.

In accordance with yet further exemplary embodiments of the disclosure, a system is provided for performing a method and/or for forming a structure as described herein.

These and other embodiments will become readily apparent to those skilled in the art from the following detailed description of certain embodiments having reference to the attached figures; the invention not being limited to any particular embodiment(s) disclosed.

### BRIEF DESCRIPTION OF THE DRAWINGS

FIG. 1 illustrates a method in accordance with one or more embodiments of the disclosure.

FIG. 2 illustrates a deposition method in accordance with one or more embodiments of the disclosure.

FIG. 3 illustrates an example of a substrate processing apparatus in accordance with one or more examples of the disclosure.

FIG. 4 illustrates an example of a structure that forms part of a device in accordance with one or more examples of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of methods, structures, devices and systems provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

As used herein, the term “and/or” includes any and all combinations of one or more of the associated listed items. Unless otherwise noted, expressions such as “at least one of,” when preceding a list of elements, modify the entire list of elements and do not necessarily modify the individual elements of the list.

As used herein, the singular forms “a,” “an,” and “the” are intended to include the plural forms as well, unless the context indicates otherwise. It will be further understood that the terms “includes,” “comprises,” “including,” and/or “comprising” used herein specify the presence of stated features, integers, steps, processes, members, components, and/or groups thereof, but do not preclude the presence or addition of one or more other features, integers, steps, processes, members, components, and/or groups thereof.

As used herein, the term “substrate” can refer to any underlying material or materials that may be used to form, or upon which, a device, a circuit, or a film may be formed. A substrate can include a bulk material, such as silicon (e.g., single-crystal silicon), other Group IV materials, such as germanium, or compound semiconductor materials, such as Group III-V or Group II-VI semiconductors, and can include one or more layers overlying or underlying the bulk material.

In some embodiments, “film” refers to a layer extending in a direction perpendicular to a thickness direction. In some embodiments, “layer” refers to a material having a certain thickness formed on a surface and can be a synonym of a film or a non-film structure. A film or layer may be constituted by a discrete single film or layer having certain characteristics or multiple films or layers, and a boundary between adjacent films or layers may or may not be clear and may or may not be established based on physical, chemical, and/or any other characteristics, formation processes or sequence, and/or functions or purposes of the adjacent films or layers. The layer or film can be continuous—or not. Further, a single film or layer can be formed using one or more deposition cycles and/or one or more deposition and treatment cycles.

As used herein, the term “structure” can refer to a partially or completely fabricated device structure. By way of examples, a structure can be a substrate or include a substrate with one or more layers and/or features formed thereon.

As used herein, the term “cyclical deposition process” or “cyclic deposition process” can refer to a vapor deposition process in which deposition cycles, typically a plurality of consecutive deposition cycles, are conducted in a process chamber. Cyclic deposition processes can include, for example, cyclic chemical vapor deposition (CCVD) and/or atomic layer deposition (ALD) processes.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, etc. in some embodiments. Further, in this disclosure, the terms “comprising,” “including,” “constituted by” and “having” can refer independently to “typically or broadly comprising,” “comprising,” “consisting essentially of,” or “consisting of” in some embodiments. In this disclosure, any defined meanings do not necessarily exclude ordinary and customary meanings in some embodiments.

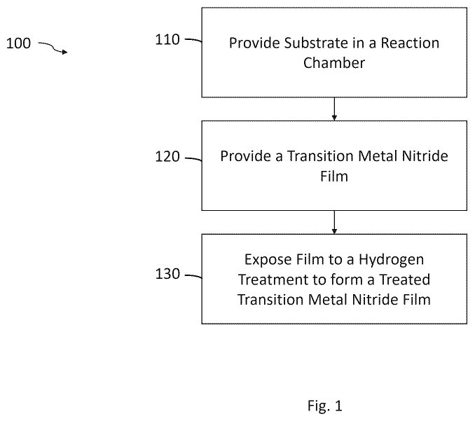

FIG. 1 illustrates a method of forming a thin film on a substrate in accordance with exemplary embodiments of the disclosure. Method 100 includes the step of providing a substrate within a reaction chamber (step 110), providing a transition metal nitride film on the substrate (step 120), and exposing the film to a hydrogen treatment to form a treated transition metal compound film (step 130).

During step 110, a substrate is provided into a reaction chamber. In accordance with examples of the disclosure, the reaction chamber can form part of a chemical vapor deposition reactor, such as a chemical vapor deposition (CVD) reactor, an atomic layer deposition (ALD) reactor, or the like. Various steps of methods described herein can be performed within a single reaction chamber or can be performed in multiple reaction chambers, such as reaction chambers of a cluster tool.

During step 110, the substrate can be brought to a desired temperature and/or the reaction chamber can be brought to a desired pressure, such as a temperature and/or pressure suitable for subsequent steps. By way of examples, a temperature (e.g., of a substrate or a substrate support) within a reaction chamber can be between about 300 and about 550° C. By way of examples, a pressure within a reaction chamber can be less than or equal to 300 torr.

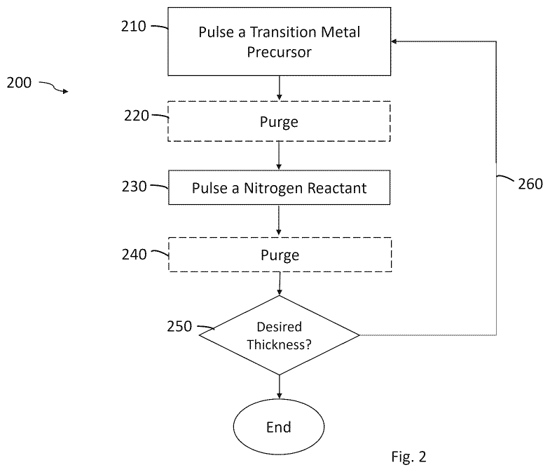

During step 120, a transition metal nitride is provided on the substrate. In some embodiments, a transition metal nitride film is present on the surface of the substrate, In some embodiments, the transition metal nitride film is deposited in the reaction chamber. In some embodiments, the transition metal nitride film is deposited by a chemical vapor deposition (CVD), cyclic chemical vapor deposition (CCVD), or atomic layer deposition (ALD) process. An exemplary method 200 of deposition is illustrated in FIG. 2.

FIG. 2 illustrates a method 200 suitable for step 120 in FIG. 1. Method 200 includes a step of pulsing a transition metal precursor 210 to the reaction chamber and a step of pulsing a nitrogen reactant 230 to the reaction chamber. Method 200 can also include an optional purge step 220 after the step of pulsing a transition metal precursor 210 and/or an optional purge step 240 after the step of pulsing a nitrogen reactant 230. The optional purge steps 220 and 240 may remove gases, precursors, reactants, and/or by-products from the reaction chamber. As illustrated, method 200 can include repeating the steps of pulsing a transition metal precursor 210 and pulsing a nitrogen reactant 230, and optionally the purge steps of 220 and 240, a number of times (loop 260) until the steps have been repeated a desired number of times and/or the deposited film reaches a desired thickness. In some embodiments, the desired thickness may be less than about 100 Angstroms, less than about 50 Angstroms, or greater than between about 8 Angstroms, or greater than about 20 Angstroms.

In some embodiments, the step of pulsing a nitrogen reactant 230 may be performed before the step of pulsing a transition metal precursor 210. In some embodiments, the steps of pulsing a transition metal precursor 210 and pulsing a nitrogen reactant 230 may at least partially overlap in time. In some embodiments, a nitrogen reactant is continuously provided throughout the method 200. In some embodiments, no plasma is produced during method 200.

In some embodiments, the transition metal precursor comprises a transition metal. In some embodiments, the transition metal precursor comprises a Group 6 metal. In some embodiments, the transition metal precursor comprises molybdenum or tungsten. Exemplary transition metal precursors of step 210 includes metalorganic precursors. In some embodiments, the transition metal precursor comprises amido groups. In some embodiments, the transition metal precursor comprises one or more imido groups. In some embodiments, the transition metal precursor comprises at least one amido group and at least one imido group. In some embodiments, the transition metal precursor comprises a transition metal imido complex. By way of particular examples, the transition metal precursor can be or include bis(tert-butylimido) bis(dimethylamido)tungsten(vi), or bis(tert-butylimido) bis(dimethylamido)molybdenum, or the like.

Exemplary reactants provided during step 230 include nitrogen-containing reactants, such as one or more of ammonia (NH₃), hydrazine (N₂H₄), nitrogen (N₂), a mixture of nitrogen (N₂) and hydrogen (H₂), or the like.

Additionally, a carrier and/or inert gas can be co-flowed throughout method 200 or during any of the sub-steps of method 200. By way of example, a carrier and/or an inert gas can be one or more of helium, argon, or nitrogen.

By way of examples, a temperature (e.g., of a substrate or a substrate support) within a reaction chamber during method 200 can be between about 300° C. and about 550° C., or between about 400° C. and about 525° C., or between about 475° C. and about 510° C. A pressure within a reaction chamber during method 200 can be less than about 300 Torr, or less than about 200 Torr, or between about 1 Torr and about 100 Torr.

Turning again to FIG. 1, during step 120 a transition metal nitride provided on the substrate comprises one or more transition metals and nitrogen. In some embodiments, the transition metal nitride can be represented as MₓN, where M is one or more transition metals, x varies from about 1 to about 2.5, or about 1.1 to about 2.1. In other embodiments, the transition metal nitride film comprises one or more transition metals, carbon, and nitrogen. In some embodiments, the transition metal nitride can be represented as MₓN_{y}C_{z}, where M is one or more transition metals; x varies from about 0.75 to about 1.25, or about 0.9 to about 1.1; y varies from about 1.05 to about 1.25, or about 1.1 to about 1.2; and z varies from about 0.6 to about 0.8, or about 0.65 to 0.75. In other embodiments, the transition metal nitride film comprises one or more transition metals, oxygen, carbon, and nitrogen. In some cases, the transition metal nitride film consists essentially of one or more transition metals, oxygen, carbon, and nitrogen. In some embodiments, the transition metal nitride can be represented as MₓN_{y}C_{z}O_{w}, where M is one or more transition metals; x varies from about 0.75 to about 1.25, or about 0.9 to about 1.1; y varies from about 1.05 to about 1.25, or about 1.1 to about 1.2; z varies from about 0.6 to about 0.8, or about 0.65 to 0.75; and w varies from about 0 to 0.7, or about 0.4 to 0.6, or about 0.45 to about 0.55. In some embodiments, the transition metal nitride film further comprises silicon. In some cases, the transition metal nitride film consists essentially of one or more transition metals, oxygen, carbon, nitrogen, and silicon. In some embodiments, the transition metal is molybdenum. In some embodiments, the transition metal nitride film consists essentially of molybdenum, oxygen, carbon, nitrogen, and silicon. In some embodiments, the transition metal nitride film comprises C═C bonds. In some embodiments, the transition metal is tungsten. In some embodiments, the transition metal nitride film consists essentially of tungsten and nitrogen. In some embodiments, the transition metal nitride film is amorphous.

In some embodiments, the transition metal nitride film may comprise an atomic percentage of transition metal between about 20 at % and about 75 at%, or about 25 at % to 70 at %, or about 30 at % to about 50 at %. The transition metal nitride film may comprise an atomic percentage of nitrogen between about 20 at % and about 40 at %, or about 25 at % to about 35 at %. In some embodiments, the transition metal nitride film comprises an atomic percentage of oxygen between about 0 at % and about 30 at %, or about 15 at % to about 25 at %. In some embodiments, the transition metal nitride film comprises an atomic percentage of carbon between about 15 at % and about 35 at %, or about 20 at % to about 25 at %.

In some embodiments, the resistivity of the transition metal nitride film has a resistivity from about 2600 μΩ cm to about 4000 μΩ cm, or about 2700 μΩ cm to about 3000 μΩ cm for thicknesses greater than about 20 Angstroms. In some embodiments, the transition metal nitride film has a resistivity from about 26000 to about 40000 μΩ cm for thicknesses less than about 20 Angstroms. In some embodiments, the transition metal nitride film has an intrinsic work function between about 4.6 and 4.85 eV.

In the illustrated example, method 100 further includes exposing the transition metal nitride film to a hydrogen treatment to form a treated transition metal compound film in step 130. The hydrogen treatment comprises exposing the transition metal nitride film to hydrogen. In some embodiment, the transition metal nitride may be exposed to the hydrogen treatment for about 0.1 minutes to about 40 minutes, or about 10 minutes to about 30 minutes, or about 1 minutes to about 20 minutes. In some embodiments, hydrogen is flowed into the reaction chamber at about 10 to 50 slm. In some embodiments, the transition metal nitride film is exposed only to a gas consisting essentially of hydrogen (H₂) and, optionally, one or more inert/carrier gases during the hydrogen treatment. In some embodiments, the film is exposed only to gases consisting essentially of hydrogen during the hydrogen treatment. In some embodiments, the hydrogen treatment is a thermal process, and no plasma may be present during the hydrogen treatment.

In some embodiments, the step 130 of exposing the transition metal nitride film to the hydrogen treatment is performed after providing the transition metal nitride film at step 120. In other embodiments, the step 130 of exposing the transition metal nitride film to the hydrogen treatment is performed at least partially concurrent with the method 200 of depositing the transition metal nitride film. In other embodiments, the step 130 of exposing the transition metal nitride film to the hydrogen treatment is performed during the method 200 of depositing the transition metal nitride film.

According to one or more embodiments, a pressure in the reaction chamber during the step 130 of exposing the transition metal nitride film to the hydrogen treatment is less than about 300 Torr, or less than about 200 Torr, and/or greater than 0.5 Torr, or between about 1 Torr and about 100 Torr.

According to one or more embodiments, a temperature in the reaction chamber during the step of exposing the transition metal nitride film to the hydrogen treatment at step 130 is from about 300° C. and about 550° C. , or between about 400° C. and about 525° C., or between about 475° C. and about 510° C.

The step 130 of exposing the transition metal nitride film to the hydrogen treatment forms a treated transition metal compound film. In some embodiments, the hydrogen treatment may form a treated transition metal nitride film by changing the composition and/or properties of the transition metal nitride film. In some embodiments, the hydrogen treatment may form a treated transition metal carbide film from the transition metal nitride film. In such embodiments, the hydrogen treatment may reduce an amount of metal to nitrogen bonds and increase an amount of metal to carbon bonds. Not to be bound by theory, in some cases, the hydrogen treatment is thought to break some of the C═C bonds in the transition metal nitride film; such bonds may be present in the transition metal precursor. The hydrogen treatment may break some C═C bonds in the transition metal nitride film and form some bonds between the transition metal and carbon. The hydrogen treatment may lower an amount of nitrogen in the transition metal nitride film. In some embodiments, the treated transition metal compound film comprises less nitrogen than the transition metal nitride film. In some embodiments, the treated transition metal compound film can be represented as MₓN_{y}C_{z}, where M is one or more transition metals; x varies from about 0.75 to about 1.25, or about 0.9 to about 1.1; y varies from 0.15 to 0.35, or about 0.2 to 0.3; z varies from about 0.6 to about 0.8, or about 0.65 to 0.75; and w varies from 0 to 0.7, or about 0.4 to 0.6, or about 0.45 to about 0.55. In some embodiments, the treated transition metal compound film can be represented as MₓN_{y}C_{z}O_{w}, where M is one or more transition metals; x varies from about 0.75 to about 1.25, or about 0.9 to about 1.1; y varies from 0.15 to 0.35, or about 0.2 to 0.3; z varies from about 0.6 to about 0.8, or about 0.65 to 0.75; and w varies from 0 to 0.7, or about 0.4 to 0.6, or about 0.45 to about 0.55. In some embodiments, the treated transition metal compound film comprises an atomic percentage of nitrogen between about 5 at % and about 30 at %, or about 7 at % and 15 at %. In some embodiments the treated transition metal compound film has a ratio of transition metal atoms to nitrogen atoms of about 2.5:1 to about 5:1, or about 3:1 to about 4:1. In some embodiments, the treated transition metal compound film comprises substantially the same amount of transition metal, carbon, and oxygen of the transition metal nitride film. In some embodiments, the treated transition metal compound film comprises substantially the same amount transition metal, oxygen, and carbon as the transition metal nitride film. In some embodiments, a ratio between the transition metal and carbon in the transition metal nitride film is within about 10%, 5%, 2%, or 1% of a ratio between transition metal and carbon in the treated transition metal compound film.

In some embodiments, the step of exposing the transition metal nitride film to the hydrogen treatment at least partially overlaps with the step of depositing a transition metal nitride film.

The hydrogen treatment may lower the resistivity of the transition metal nitride film, such that the treated transition metal compound film has a lower resistivity than the transition metal nitride film. The treated transition metal compound film may have a resistivity of about 300 μΩ cm to about 600 μΩ cm, or about 350 μΩ cm to about 500 μΩ cm, or about 375 μΩ cm to about 425 μΩ cm for thicknesses greater than about 20 Angstroms. The treated transition metal compound film may have a resistivity less than about 4000 μΩ cm, or less than about 3250 μΩ cm, or less than about 2600 μΩ cm for thicknesses less than about 20 Angstroms. In some embodiments, the treated transition metal compound film may have a resistivity from about 60% to about 90% less, or about 80 % to about 88% less than the resistivity of the transition metal nitride film. The hydrogen treatment may increase the density of the transition metal compound film such that the treated transition metal compound film has a higher density than the transition metal nitride film. In some embodiments, the treated transition metal compound film may have a density from about 25% to about 50% greater, or about 30 % to about 45% greater, than the density of the transition metal nitride film. The hydrogen treatment may decrease the thickness of the transition metal nitride film such that the treated transition metal compound film has a smaller thickness than the transition metal nitride film. In some embodiments, the treated transition metal compound film may have a thickness from about 20% to about 40% smaller, or about 25 % to about 35 smaller than the thickness of the transition metal nitride film. The hydrogen treatment may increase the work function of the transition metal nitride film, In some embodiments, the work function of the transition metal compound film is about 30 to about 50 meV higher than the transition metal nitride film.

The hydrogen treatment may remove constituent atoms of the transition metal nitride film. The hydrogen treatment may change the bonding structure of the transition metal nitride film. In some embodiments, the hydrogen treatment may not add any material to the transition metal nitride film. In some embodiments, the hydrogen treatment may not add any material to the transition metal nitride film other than hydrogen.

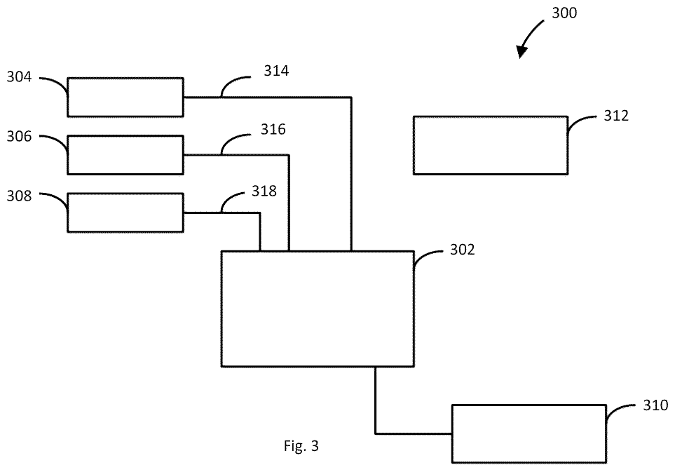

FIG. 3 illustrates an example of a substrate processing apparatus 300 in accordance with one or more examples of the disclosure. Apparatus 300 can be used to perform a method as described herein and/or form a structure or device portion as described herein.

In the illustrated example, apparatus 300 includes one or more reaction chambers 302, a transition metal precursor gas source 304, a nitrogen reactant gas source 306, a hydrogen gas source 308, an exhaust source 310, and a controller 312.

Reaction chamber 302 can include any suitable reaction chamber, such as an atomic layer deposition (ALD) or chemical vapor deposition (CVD) reaction chamber.

Transition metal precursor gas source 304 can include a vessel and one or more transition metal precursors as described herein-alone or mixed with one or more carrier (e.g., inert) gases. Nitrogen reactant gas source 306 can include a vessel and one or more nitrogen reactants as described herein-alone or mixed with one or more carrier gases. Hydrogen gas source 308 can include one or more hydrogen-containing gases, such as H₂, as described herein. Although illustrated with three gas sources 304-308, apparatus 300 can include any suitable number of gas sources. Gas sources 304-308 can be coupled to reaction chamber 302 via lines 314-318, which can each include flow controllers, valves, heaters, and the like.

Exhaust source 310 can include one or more vacuum pumps.

Controller 312 includes electronic circuitry and software to selectively operate valves, manifolds, heaters, pumps and other components included in the apparatus 300. Such circuitry and components operate to introduce precursors, reactants, and gases from the respective sources 304-308. Controller 312 can control timing of gas pulse sequences, temperature of the substrate and/or reaction chamber, pressure within the reaction chamber, and various other operations to provide proper operation of the apparatus 300. Controller 312 can include control software to electrically or pneumatically control valves to control flow of precursors, reactants and purge gases into and out of the reaction chamber 302. Controller 312 can include modules such as a software or hardware component, e.g., a FPGA or ASIC, which performs certain tasks. A module can advantageously be configured to reside on the addressable storage medium of the control system and be configured to execute one or more processes or methods, as described herein.

Other configurations of apparatus 300 are possible, including different numbers and kinds of precursor and reactant sources and purge gas sources. Further, it will be appreciated that there are many arrangements of valves, conduits, precursor sources, and purge gas sources that may be used to accomplish the goal of selectively feeding gases into reaction chamber 302. Further, as a schematic representation of a system, many components have been omitted for simplicity of illustration, and such components may include, for example, various valves, manifolds, purifiers, heaters, containers, vents, and/or bypasses.

During operation of apparatus 300, substrates, such as semiconductor wafers (not illustrated), are transferred from, e.g., a substrate handling system to reaction chamber 302. Once substrate(s) are transferred to reaction chamber 302, one or more gases from gas sources 304-308, such as precursors, reactants, carrier gases, and/or purge gases, are introduced into reaction chamber 302.

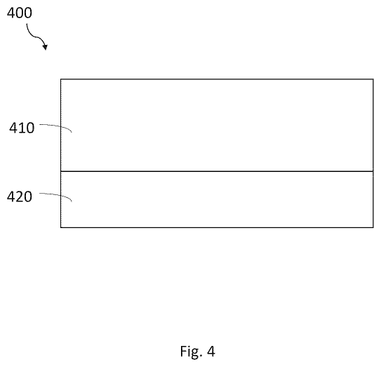

FIG. 4 illustrates a structure/a portion of a device 400 in accordance with additional examples of the disclosure. Device or structure 400 includes a substrate 420 and a layer comprising transition metal compound 410. The transition metal compound layer 410 may be formed by a method described in this disclosure. In some embodiments, the transition metal compound layer may have a resistivity of less than about 400 μΩ cm, or from about 300 μΩ cm to about 600 μΩ cm, or about 350 μΩ cm to about 500 μΩ cm, or about 375 μΩ cm to about 425 μΩ cm. In some embodiments, the transition metal compound layer has a thickness less than 50 Angstroms or about 10 Angstroms to about 40 Angstroms. In some embodiments, the transition metal compound film can be represented as MₓN_{y}C_{z}O_{w}, where M is one or more transition metals; x varies from about 0.75 to about 1.25, or about 0.9 to about 1.1; y varies from 0.15 to 0.35, or about 0.2 to 0.3; z varies from about 0.6 to about 0.8, or about 0.65 to 0.75; and w varies from about 0 to 0.7, or about 0.4 to 0.6, or about 0.45 to about 0.55. In accordance with further examples, layer 410 can be or include a treated transition compound layer as described herein.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

1. A method of forming a thin film comprising:
providing a substrate in a reaction chamber;
depositing a transition metal nitride film on the substrate, wherein the depositing the transition metal nitride film comprises:
pulsing a transition metal precursor, wherein the transition metal precursor comprises a metalorganic precursor comprising at least one amido group, and
pulsing a nitrogen reactant; and
exposing the transition metal nitride film to a hydrogen treatment form a treated transition metal compound film, wherein the treated transition metal compound film comprises less nitrogen than the transition metal nitride film,
wherein a pressure during the exposing the transition metal nitride film to the hydrogen treatment is less than about 200 Torr, and
wherein a temperature within the reaction chamber during the exposing the transition metal nitride film to the hydrogen treatment is from about 300 °C to about 550 °C.

2. The method of claim 1, wherein the transition metal nitride film comprises molybdenum.

3. The method of claim 1, wherein the exposing the transition metal nitride film to the hydrogen treatment comprises exposing transition metal nitride to H₂.

4. The method of claim 1, wherein the exposing the transition metal nitride film to the hydrogen treatment is a thermal process.

5. The method of claim 1, wherein a pressure during the exposing the transition metal nitride film to the hydrogen treatment is from about 100 Torr to about 200 Torr.

6. The method of claim 1, wherein the treated transition metal compound film is represented by the formula MₓN_{y}C_{z}O_{w}, where M is one or more transition metals; x is between about 0.75 to about 1.25, y is between about 0.15 to about 0.35, z is between about 0.6 to about 0.8, and w is between about 0.4 to 0.6.

7. The method of claim 1, wherein a temperature during the exposing the transition metal nitride film to the hydrogen treatment is from about 400 °C to about 525 °C.

8. The method of claim 1, wherein the exposing the transition metal nitride film to the hydrogen treatment comprises exposing the transition metal nitride film to hydrogen for about 0.1 minutes to about 40 minutes.

9. The method of claim 1, wherein the depositing the transition metal nitride film comprises an atomic layer deposition (ALD) process.

10. The method of claim 1, wherein the depositing the transition metal nitride film comprises repeating the pulsing the transition metal precursor and the pulsing the nitrogen reactant until the transition metal nitride film reaches a predetermined thickness.

11. The method of claim 1, wherein the transition metal nitride film has a thickness less than about 100 Angstroms.

12. A method of forming a thin film comprising:
providing a substrate in a reaction chamber;
depositing a transition metal nitride film on the substrate, wherein the transition metal nitride film comprises a transition metal, oxygen, carbon, and nitrogen, wherein the transition metal nitride film has a resistivity from about 2600 μΩ cm to about 4000 μΩ cm; and
exposing the transition metal nitride film to a hydrogen treatment to form a treated transition metal compound film, wherein the treated transition metal compound film has a resistivity from about 300 μΩ cm to about 600 μΩ cm,
wherein the treated transition metal compound film comprises substantially the same amount of the transition metal, oxygen, and carbon as the transition metal nitride film.

13. The method of claim 12, wherein the transition metal nitride film comprises an atomic percentage of nitrogen between about 20 at % and about 40 at%.

14. The method of claim 13, wherein the treated transition metal compound film comprises an atomic percentage of nitrogen between about 5 at % and about 30 at%.

15. The method of claim 12, wherein the transition metal nitride film comprises an atomic percentage of carbon between about 15 at % and about 35 at %.

16. The method of claim 12, wherein a ratio between the transition metal and carbon in the transition metal nitride film is within about 10% of a ratio between transition metal and carbon in the treated transition metal compound film.

17. The method of claim 12, wherein the exposing the transition metal nitride film to the hydrogen treatment lowers the number of C═C bonds in the transition metal nitride film.

18. The method of claim 12, wherein the exposing the transition metal nitride film to the hydrogen treatment at least partially overlaps with the depositing the transition metal nitride film.

19. The method of claim 12, wherein the transition metal nitride film has a thickness less than about 100 Angstroms.

20. The method of claim 12, wherein the depositing the transition metal nitride film comprises:
pulsing a transition metal precursor, wherein the transition metal precursor comprises a metalorganic precursor, and
pulsing a nitrogen reactant.
